(19) United States
(12) Patent Application Publication
(10) Pub. No.: US 2008/0274278 A1
(43) Pub. Date: Nov. 6, 2008

(54) Method for Depositing in Particular Metal Oxides by Means of Discontinuous Precursor Injection

(76) Inventors: Peter Baumann, Aachen (DE); Marcus Schumacher, Kerpen (DE); Johannes Lindner, Roetgen (DE)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 10/599,323

(22) PCT Filed: Mar. 9, 2005
(86) PCT No.: PCT/EP2005/051050

§ 371 Date: Jul. 14, 2008

(30) Foreign Application Priority Data
Mar. 27, 2004 (DE) 10 2004 015 174.1

(51) Int. Cl. C23C 16/00

(52) U.S. Cl. 427/250; 118/715

(57) ABSTRACT

The invention relates to a method for the deposition of at least one layer on at least one substrate in a process chamber, whereby the layer comprises at least one component. The at least one first metal component is vaporised in a particularly conditioned carrier gas by means of a non-continuous injection of a starting material in the form of a liquid or dissolve in a liquid and at least one second component as chemically-reactive starting material. The starting materials are alternately introduced into the process chamber and the second starting material is a chemically-reactive gas or a chemically-reactive liquid.

The invention relates to a method for depositing at least one layer on at least one substrate in a process chamber, the layer comprising at least two components, at least a first metallic component being vaporized into a carrier gas, in particular a heated carrier gas, by means of a discontinuous injection of a first starting material in the form of a liquid or a first starting material dissolved in a liquid, and a second component being supplied as a chemically reactive starting material, characterized in that the starting materials are introduced alternately into the process chamber.

For depositing metal-oxidic layers such as hafnium oxide, or aluminum oxide, or else praseodymium oxide, methods such as Molecular Beam Epitaxy (MBE), Metal-Organic Chemical Vapor Deposition (MOCVD) and Atomic Layer Deposition (ALD) are presented in the literature.

MBE does not achieve conformal edge coverage when thin layers are deposited, while MOCVD and ALD methods ensure good edge coverage when depositing on structured substrates. Conventional MOCVD methods, which are based on vaporization of liquid or solid precursors, usually use heated precursor containers (bubblers) for transforming the starting substances into the gas phase by means of a carrier gas. Most precursors for oxidic materials (or corresponding dilute solutions) are usually relatively nonvolatile and chemically and thermally unstable, and change or decompose under these thermal conditions, which has the effect that the deposition is not reproducible. In particular, complete saturation of the gas phase, and consequently high growth rates, can only be achieved with difficulty by means of such arrangements. Therefore, various liquid precursor supply systems, based on abrupt vaporization of small amounts of precursor by direct contact with heated surfaces, have been developed for MOCVD. This process entails disadvantages, such as vaporization characteristics that change over time as a result of deposits on the heated surfaces and particle formation. It is reported that periodic injection of liquid precursors into a heated volume with subsequent contactless vaporization can be used to avoid these disadvantages, though not described for a number of sources (U.S. Pat. No. 5,945,162). In the case of conventional MOCVD, the poor atomic precision causes inadequacies with regard to layer thickness control, for example when depositing nanolaminates. By contrast with ALD methods, inadequate edge coverage is also often reported when conventional MOCVD is used for depositing on highly structured substrates.

However, ALD methods rely on a very small number of available precursors, which are often based on chlorine compounds. The alternating introduction of gaseous H₂O, for example, into the process chamber as an oxidant thereby produces HCl, which however is quite difficult to handle safely as a waste gas constituent.

Specifically, ALD methods, which rely on sources of solid substances (bubblers), usually have problems with inadequately achievable gas phase saturation, since bubbler systems cannot always generate sufficient starting substance on account of limited sublimation processes. In the case of systems with more than one substrate to be coated and relatively large reaction chamber volumes, this problem is particularly marked. This phenomenon results in a growth rate that is inadequate for production purposes, and possibly inhomogeneous coating of the substrates.

ALD relies in principle on alternating, self-limiting chemical reactions for the successive deposition of monolayers. This is carried out by complicated switching of valves. Pumping and purging cycles are introduced between the supplying of the individual reagents. This leads to low throughputs and is a disadvantage, in particular in the case of single-wafer ALD systems.

Even the production of multi-component oxides is made more difficult, or even entirely impossible, when ALD methods are used, since the starting substances are not already mixed in the gas phase as they are in the case of standard MOCVD methods. In particular, therefore, ALD methods are unable in principle to produce layers that allow mixtures of a number of metal oxides of different types of material to change in situ during the growth process with a gradient-like variation. Furthermore, ALD also exhibits a non-linear growth in dependence on the layer thickness, which specifically makes it much more difficult to maintain control over the processes in the case of very small layer thicknesses.

In order to ensure the further development of electronic components, for example for CMOS or DRAM applications, high-k materials inter alia are sought as alternatives to SiO₂ as dielectric. As candidates for this, aluminum oxide, hafnium oxide or praseodymium oxide, but specifically also multi-component oxides, are of especially great interest, since they have outstanding properties with regard to the dielectric constant and leakage currents. Recent findings even demonstrate improved material properties by laminating or mixing these metal oxides with one another or, to improve the thermal stability, also by adding silicon.

In general, pure materials such as pure HfO₂, Al₂O₃ or else Pr₂O₃ do not appear to satisfy the requirements with regard to the dielectric constant, the leakage current and the thermal stability simultaneously. A mixture of such metal oxides or similar metal oxides or a doping seems to be the solution here. According to the current state of the art, standard ALD or MBE methods are not suitable production solutions for the described layer deposition of multi-component materials owing to very low growth rates. There is therefore a need for a method which ensures on an industrial scale the low-cost, efficient deposition of highly pure, multi-component metal oxides on the basis for example of hafnium oxide, or aluminum oxide, with a good reproducibility, high uniformity and good edge coverage even on highly structured substrates.

In this respect, it is intended to develop a method which in principle combines the advantages of the classic MOCVD and ALD methods, while obviating the respective disadvantages. Atomic layer thickness controllability, high growth rate as a result of freely adjustable, adequate gas phase saturation and the possibility of normal deposition on highly structured topographies are to be achieved while at the same time avoiding inadequate gas phase saturation, complicated valve switching operations for growing or purging cycles, limited possibilities in the deposition of multi-component material systems and at the same time little choice of source materials.

DE 103 42 890 describes an apparatus and a method with which the pulse width or the pauses between the pulses are varied to vary the mass flow of the precursors.

DE 101 14 956 and DE 100 57 491 A1 describe the use of various starting materials for depositing layers by the method mentioned at the beginning.

An object of the invention is to improve the generic method further to the extent that the weaknesses described above are avoided to the greatest extent, and an atomic layer deposition is nevertheless possible.

The object is achieved by the invention specified in the claims, each of the claims describing an independent solution.

Claim 1 provides first and foremost that the starting materials are introduced alternately into the process chamber. The invention consequently relates to a method in which a starting substance in the form of a liquid or in the form of a solid dissolved in a liquid is introduced into a heated volume by means of discontinuous injection. This can take place by atomizing with a suitable, valve-controlled nozzle. When the liquid is introduced into the heated volume of a carrier gas, the energy of vaporization is extracted from the carrier gas. The mass flow is in this case set per pulse in such a way that the carrier gas in the vaporization chamber is saturated. Preferably, at least one vaporized metal starting substance and at least one reactive gas are used in alternation here. Between the two gas pulses, the process chamber or the vaporization chamber may be purged with a carrier gas. However, it is also provided that the process chamber or the vaporization chamber is evacuated by pumping between the two gas pulses. If the two starting materials are vaporized in a common vaporization chamber, it proves to be advantageous also to purge or evacuate this chamber between the pulses. In addition, it may be provided that the vaporization of the individual starting materials is performed in separate vaporization chambers. Here it is not necessary to purge or evacuate the vaporization chamber between the pulses, but the process chamber should in this case also be purged or evacuated between the pulses. Here, too, a pause can be left between switching over from one starting substance to the other. During the pause, an inert carrier gas may be fed in. However, it is also provided in this case that the apparatus, in particular the process chamber, is evacuated within the pauses. The purging of the process chamber or the evacuation of the process chamber takes place with the substrate holder heated. One or more substrates that are coated when the method is carried out, lie on the substrate holder. The mass flow may in this case be set such that monolayer on monolayer is deposited on the substrate in a pulsed manner. In the pauses between the individual growth steps, during which a monolayer is respectively deposited, the molecules attached on the surface have time to arrange themselves. The direct injection of liquid or dissolved starting substances into one or more heated volumes achieves complete saturation of the gas phase, while at the same time making it possible to dispense with complicated valve switching operations to accomplish the growing or purging cycles. The claimed method and the claimed apparatus consequently not only make the contactless vaporizing of metal or metal-oxide source materials possible. A high gas phase saturation in the process chamber is also achieved. This ensures the efficient, reproducible and particle-free deposition of metal oxides, metal nitrides or metals, with a high throughput. The complete gas phase saturation also makes simultaneous deposition on a number of substrates possible. These substrates may be stacked one above the other or lie side by side. The substrates may in this case be horizontally oriented or vertically oriented. Local depletions, and accompanying inhomogeneous layer growth, are avoided. While the component of one layer is forming on the substrate surface after an injection pulse, the starting material of the other component can be supplied. For example, further metal oxides can be admixed. This also takes place by means of liquid injection. The injection rate or the pulse-pause ratio can in this case be freely selected to the greatest extent. To influence the mass flow, the admission pressure in the supply line to the injection nozzle or the mass flow per unit of time can also be varied. It is regarded as advantageous that simple or mixed or doped metal oxides or metal nitrides can be deposited by the method. Variation of the injection admission pressure or the induction frequency or the pulse/pause ratio allows layers of different qualities to be deposited directly one on top of the another, without longer pauses being required between the depositing of the successive layers. The method according to the invention can also be used for depositing gradient structures. This takes place by continuous variation of the masses and parameters during the depositing of a layer. As a result, a layer composition that changes continuously in the vertical direction is formed. With this method, continuous transitions between two deposited layers can consequently also be achieved. This may take place both on planar surfaces and on highly structured surfaces, particularly those having three-dimensional structures such as trenches. The mass flows of the starting materials in the supply lines to the injector nozzles are determined by means of mass flow measurement. The following metals come into consideration in particular as metallic components: Al, Si, Pr, Ge, Ti, Zr, Hf, Y, La, Ce, Nb, Ta, Mo, Bi, Nd, Ba, Gd, Sr. The method not only allows layers comprising a number of components to be deposited, it is also possible to deposit layers which comprise one component. For example, it is possible to deposit metallic electrodes which consist of Pt or Ro. The metallic component is introduced as a metalorganic starting material. The chemically reactive starting material may in this case be oxygen or water. The organic part of the metalorganic compound is removed with it. The apparatus with which the claimed method is performed corresponds to that described by DE 103 42 890.

Exemplary embodiments of the invention are explained below with reference to accompanying drawings, in which:

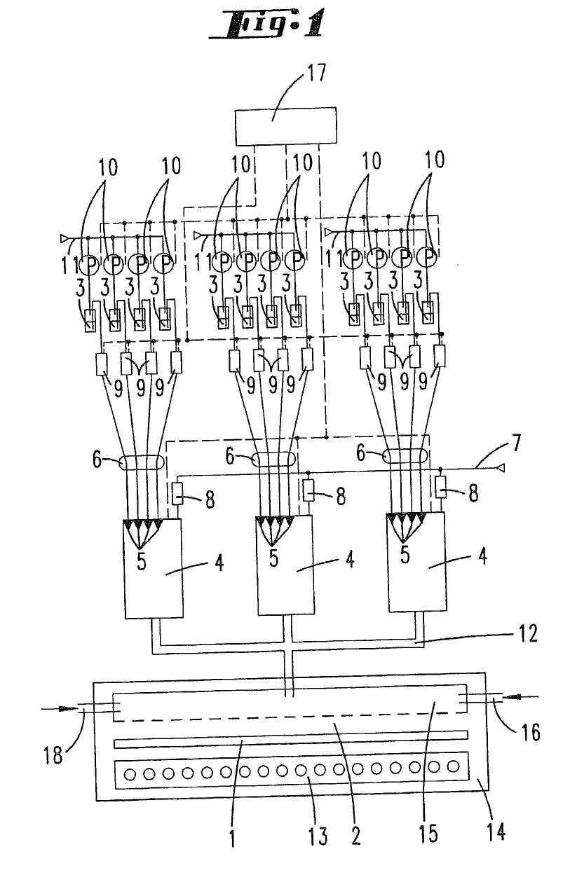

FIG. 1 shows the construction of an apparatus according to the invention in a schematic representation,

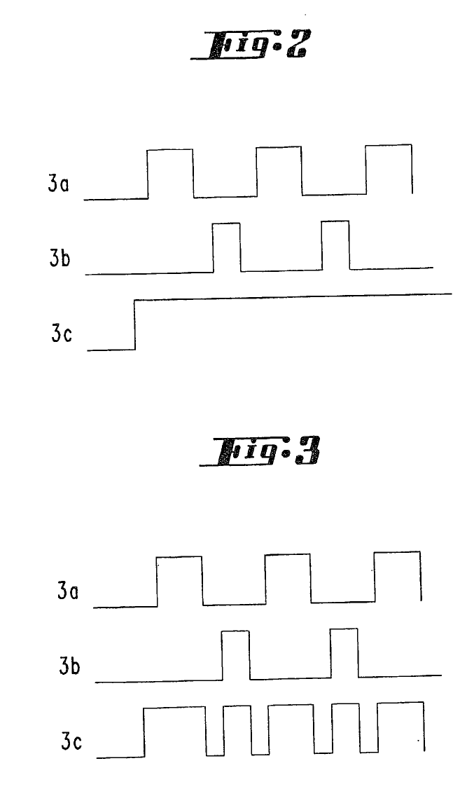

FIG. 2 shows an extract of the variation of the gas flows of the precursor (3a), reactive gas (3b) and carrier gas (3c), in dependence on the process time, and

FIG. 3 shows a representation according to FIG. 2 of a second exemplary embodiment.

FIG. 1 shows the main elements of an apparatus for the discontinuous injection of liquid or dissolved metal starting substances by means of a multi-channel injection unit 6 in a roughly schematic form. In the exemplary embodiment, the multi-channel injection unit has a number of channels 5. However, it is also provided that in each case only a single channel 5 opens out into a vaporization chamber. The exemplary embodiment shows a total of three vaporization chambers 4, each with an injection unit 6. This apparatus is intended to be used specifically for the depositing of single-component or multi-component oxides (hafnium oxide, aluminum oxide, strontium or praseodymium oxide, etc.), laminated and mixed oxidic materials and single-component or multi-component electrically conducting materials such as metal, metal oxides and electrically conducting semiconductor compounds. Then the method described above and below in detail allows the production of complex structures from passivation layers, dielectric and electrically conducting electrode materials on highly structured substrates by in-situ mass flow control of the individual sources with atomic layer thickness control, without interrupting the processing frequency.

FIG. 1 shows a reactor which has a reactor chamber 14. Connected to the reactor chamber 14 are peripheral devices that are not represented, for example a vacuum pump, for evacuating the reactor chamber 14 and the units arranged upstream of the reactor chamber. Inside the reactor chamber there is a heater 13. Located above the heater 13 is the substrate, which is indicated by the reference numeral 1. The substrate 1 rests on a substrate holder that is not represented in the drawing. Said substrate holder may be rotationally driven. Above the substrate is the process chamber 2, into which the starting materials are introduced. Serving for this purpose is a gas inlet member 15, which is disposed above the process chamber 2 and formed in the manner of a shower head. The gas inlet member 15 provides the upward delimitation of the process chamber 2. The substrate or the substrate holder (not represented) provides the downward delimitation of the process chamber 2. The reactive gases or liquids dissolved in gases and carrier gases which flow into the process chamber 2 from above flow out of the process chamber 2 via the peripheral devices. They are pumped out of the reactor chamber 14.

A supply line 12 opens out into the gas inlet member. Vaporized starting materials 3 can be introduced together with a carrier gas 7 into the gas inlet member 15 through the supply line 12.

The pipelines 12 may be heated to prevent condensation. The supply lines 12 emerge from the aforementioned vaporization chambers 4. Each of the vaporization chambers 4 has at least one injector nozzle 5. By means of the injector nozzle, liquids are sprayed into the heated gas located inside the vaporization chamber 4. The aerosol or the mist thereby produced absorbs thermal energy from the inert gas located in the vaporization chamber 4 to convert itself into the gas form.

The inert gas is introduced into the vaporization chamber 4 via a mass flow regulator 8. The inert gas 7 may be nitrogen, hydrogen or a noble gas.

Each injection nozzle 5 has an individual supply line, through which an individual liquid or a starting material dissolved in a liquid or a chemically reactive liquid flows. The mass flows of these liquids are measured by mass flow meters 9. Disposed upstream of the mass flow meters 9 are the liquid sources, in which the liquids 3 are located. Upstream of the liquid reservoirs are pressure controllers 10. The pressure controllers 10 are subjected to an inert gas 11. By means of the injector nozzles 5, the liquid components are sprayed into the vaporization chamber in a pulsed manner. The pulse widths may be varied between several seconds and a few milliseconds. The pauses between the pulses may also be varied in the same range. Accordingly, pulse frequencies of between 0.1 and 100 Hz are possible.

The apparatus serves for coating a highly structured substrate. It is also possible for a number of substrates to be disposed in the process chamber. It is then formed differently than is shown in FIG. 1. In particular, a number of substrates may be disposed parallel to one another as an assembly. The substrates may extend horizontally or vertically.

FIG. 2 shows the typical variation of the pulses with which the precursors 3a, that is to say the metallic components and the reactive starting materials 3b, that is to say a chemically reactive gas or a chemically reactive liquid, are introduced into the respective vaporization chamber 4. Also shown in FIG. 2 is the variation over time of the flow of the carrier gas 3c, which is an inert gas.

It can be gathered that, before the first pulse, with which the metallic starting material 3a is brought into the vaporization chamber 4, the inert carrier gas 3c is introduced into the vaporization chamber 4. After completion of the pulse with which the metallic starting material 3a is introduced into the vaporization chamber 4, there is at first a pause. The carrier gas stream 3c may in this case be so great that a complete gas change takes place during the pause, and particularly during the pulse, inside the vaporization chamber 4.

The pulse pause is followed by the spraying-in of the chemically reactive liquid 3b. Instead of a chemically reactive liquid 3b, it is also possible, however, for a chemically reactive gas to be introduced. In the exemplary embodiment, the pulse length within which the chemically reactive substance is introduced into the vaporization chamber is shorter than the pulse width of the metallic substance. After completion of the pulse, there is once again a pulse pause, in which only carrier gas 3c flows into the vaporization chamber 4. Here, too, a complete gas change takes place inside the vaporization chamber 4 during the pulse or the pulse pause.

The precursor 3a or the reactive substance 3b may be introduced into one and the same vaporization chamber 4. However, it is also provided that the two substances 3a, 3b are introduced into different vaporization chambers 4.

In a development of the invention, it is provided that the pulses in the range of seconds are frequency-modulated from a multiplicity of pulses in the subsecond range. Here, too, it is provided that the carrier gas inside the vaporization chamber 4 is completely saturated during the pulsed introduction. Also in the case of this variant, the gas change takes place in times of less than one second.

In the case of the exemplary embodiment represented in FIG. 3, the pulse widths and pulse shapes with which the precursor 3a and the reactive substances 3b are introduced into the vaporization chamber correspond to those shown in FIG. 2. Unlike in the case of the exemplary embodiment of FIG. 2, however, the carrier gas supply is switched off after introduction of a precursor pulse 3a. In the pulse pause which then follows, the vaporization chamber is evacuated. Evacuation may take place via the process chamber. With the beginning of the pulse of the reactive substance 3b, the carrier gas 3c is again added. However, the vaporization chamber 4 is preferably flooded with carrier gas before the introduction of the reactive substance 3b, in order that the heat required for the vaporization can be extracted from said carrier gas. If, instead of a liquid reactive substance 3b, a gaseous reactive substance 3b is used, it may be introduced into the evacuated vaporization chamber 4. Here, too, it is provided that the vaporization chamber 4 is evacuated via the process chamber once the adding of the reactive substance 3b is completed.

In a further variant of the method, it is provided that a reactive gas is introduced directly into the gas inlet member 15 via a supply line 16. It is also provided that an inert gas 18 is introduced directly into the gas inlet member 15. The introduction of the chemically reactive gas 16 also preferably takes place in a pulsed manner.

The chemically reactive starting materials may be oxygen or an oxygen compound such as N₂O, H₂O or ozone. Nitrogen may also be used, however, as the reactive starting material. This is preferably brought into the vaporization chamber as N₂O or NH₃.

The liquid starting materials of the metallic type may contain the metals Al, Si, Pr, Ge, Ti, Zr, Hf, Y, La, Ce, Nb, Ta, Mo, Bi, Nd, Ba, W or Gd.

All disclosed features are (in themselves) pertinent to the invention. The disclosure content of the associated/accompanying priority documents (copy of the prior application) is also hereby incorporated in full in the disclosure of the application, including for the purpose of incorporating features of these documents in claims of the present application.

1. Method for depositing at least one layer on at least one substrate in a process chamber, the layer comprising at least two components, at least a first metallic component being vaporized into a carrier gas, in particular a heated carrier gas, by means of a discontinuous injection of a first starting material in the form of a liquid or a first starting material dissolved in a liquid, and at least a second component being supplied as a chemically reactive starting material, characterized in that the starting materials are introduced alternately into the process chamber.

2. Method according to claim 1 characterized in that the second starting material is a chemically reactive gas or a chemically reactive liquid.

3. Method according to claim 2 characterized in that the chemically reactive liquid is vaporized.

4. Method according to claim 1 characterized in that the at least two starting materials (3) are injected alternately into a vaporization chamber (4).

5. Method according to claim 1 characterized by each starting material (3) being individually associated with a vaporization chamber (4).

6. Method according to claim 5 characterized in that the process chamber (2) and optionally also the vaporization chamber (4) is purged with an inert gas (7) or evacuated after each injection.

7. Method according to claim 4 characterized in that the carrier gas (7) in the vaporization chamber (4) is saturated with the starting material as a result of the injection of the starting material.

8. Method according to claim 4 characterized in that the mass of gas that is brought into the vaporization chamber (4) with each injection pulse is determined by means of the gas admission pressure, the pulse length, the pulse pause or the mass flow.

9. Method according to claim 1 characterized in that at least one inert carrier gas (16) is introduced directly into the process chamber (2).

10. Method according to claim 1 characterized in that the chemically reactive starting material in gaseous form is introduced into the process chamber directly as a gas (18).

11. Method according to claim 1 characterized in that the chemically reactive starting material is an oxygen compound or a nitrogen compound.

12. Method according to claim 1 characterized in that the chemically reactive starting material is O₂, O₃, N₂O, H₂O or NH₃.

13. Method according to claim 1 characterized in that the process chamber is actively heated and in that the pressure in the process chamber is below or equal to 100 mbar, 50 mbar, 20 mbar or 10 mbar.

14. Method according to claim 1 characterized in that the liquid starting materials or the solid materials or liquids dissolved in a liquid contain one or more of the following metals: Al, Si, Pr, Ge, Ti, Zr, Hf, Y, La, Ce, Nb, Ta, Mo, Bi, Nd, Ba, W or Gd.

15. Method according to claim 1 characterized in that the layers are deposited conformally on highly structured structures, particularly three-dimensionally structured structures.

16. Method according to claim 1 characterized in that the deposited layers are insulating, passivating or electrically conducting.

17. Method according to claim 1 characterized in that the layers consist of metal oxides, metal nitrides or metals.

18. Method according to claim 1 characterized in that the injection occurs by injector nozzles, which can be closed by valves and set in such a way that nanolaminates, hyperstructures, nucleation layers, mixed oxides and gradient layers are produced.

19. Method according to claim 1 characterized in that a number of parallel and/or highly structured substrates are disposed side by side on at least one substrate holder, in particular a rotationally driven substrate holder.

20. Method according to claim 1 characterized in that a number of planar and/or highly structured substrates are disposed in the process chamber vertically oriented one above the other and/or horizontally oriented side by side and/or oriented at angles between vertical and horizontal.

21. Apparatus for depositing at least one layer on at least one substrate in a process chamber, the layer comprising at least two components, at least a first metallic component being vaporized into a carrier gas, in particular a heated carrier gas, by means of a discontinuous injection of a first starting material in the form of a liquid or a first starting material dissolved in a liquid, and at least a second component being supplied as a chemically reactive starting material, characterized in that the starting materials are introduced alternately into the process chamber comprising a process chamber (2), having a gas inlet member (15), with which one or more vaporization chambers (4) are associated upstream, which vaporization chambers (4) each have at least one injector unit (5) for discontinuously supplying a liquid (3).
